(19) United States
(12) Patent Application Publication
(10) Pub. No.: US 2026/0018326 A1
(43) Pub. Date: Jan. 15, 2026

(54) ON-CHIP INDUCTOR AND BROADBAND AMPLIFIER WITH ONCHIP RESONATOR INCLUDING THE ON-CHIP INDUCTOR

(71) Applicant: Telefonaktiebolaget LM Ericsson (publ), Stockholm (SE)

(72) Inventors: Ufuk ÖZDEMIR, Lund (SE); Sharath THANDAVA MURTHY, Solna (SE); Hind DAFALLAH, Lund (SE)

(21) Appl. No.: 19/139,686

(22) PCT Filed: Dec. 21, 2022
(86) PCT No.: PCT/EP2022/087343

§ 371 Date: Jun. 16, 2025

(51) Int. Cl. H01F 27/28; H01F 27/29

(52) U.S. Cl. CPC H01F 27/2804; H01F 27/292; H01F 2027/2809

(57) ABSTRACT

Provided is an on-chip inductor for realizing broadband and a flat frequency response. The on-chip inductor includes an inductor coil comprising a first sub-coil and a second sub-coil having mutual inductance, wherein the first sub-coil and the second sub-coil form a permanent electrical connection in series and the second sub-coil is placed inside the first sub-coil on the chip. Furthermore, the on-chip inductor includes terminals connected to the first sub-coil and a resistor connected in parallel to the second sub-coil.

### TECHNICAL FIELD

The present disclosure relates to a broadband amplifier with on-chip resonator. In particular, the present disclosure relates to an on-chip inductor, an amplifier including at least one on-chip inductor, and a semiconductor die having formed thereon at least one on-chip inductor for realizing broadband and a flat frequency response.

### BACKGROUND

As the demand for higher data rates increases, the challenges for circuit designers are higher bandwidths and/or higher frequency of operation at the same or lower current consumption. These challenges are, for example, relevant for the integrated circuits used in network nodes, like base stations, eNodeBs, gNodeBs, or the like. To be more specific, the circuit may be an analog front-end amplifier placed in front of a radio frequency (RF) analog to digital converter (ADC) sampling at, for example, higher than 15 GHz. The specified frequency range is, for example, from 1 GHz up to 8 GHZ (i.e., in Nyquist Zone (NZ) 1), and it is subject to evolve to higher frequencies in the coming years (higher NZs or sample rates).

Many circuit topologies have a high bandwidth at high frequencies. However, a careful comparison is important for these solutions since a 5 GHz bandwidth centered at 60 GHz and centered at 6 GHz typically does not have the same center frequency to bandwidth ratio. For a fairer comparison, a ratio should be used which is also known as Quality factor, Q-factor, or Q-ratio. The Q-factor or Q-ratio is a dimensionless parameter which describes how underdamped a resonator is.

For example, the following circuit topologies are known:

Parallel LC resonators including an inductor (indicated by L) and a capacitor (indicated by C) are widely used in RF circuits as tuned loads. Some of their advantages are (i) band-pass characteristic, which helps to filter out undesired signals and noise, (ii) low IR drop (i.e. voltage drop that appears at the resistive component of any impedance; I indicating the current, R indicating the resistor) direct current (DC) feeding supply voltage via inductor, which enables high drain-source voltage (VDS) on the transistors yielding better linearity, (iii) an output swing on the voltage supplied to the drain of a transistor (Vdd), which enables a high output compression point since the output can swing up to 2×Vdd, and (iv) resonating out load and parasitic capacitances with inductance, which enables high-frequency operation at low current consumption and low noise.

One alternative to the tuned circuitry described above are operation amplifier (op-amp) based broadband circuits. However, their high frequency of operation is limited due to the need for high unity gain bandwidth (UGB) of the op-amp, which is needed to keep the loop gain high over frequency.

Another alternative is to have a low ohmic broadband load, as in current mode logic (CML), which would operate up to very high frequencies, as done in wireline applications. The highest frequency of operation is limited by capacitances (parasitic or load) since with the impedance they form a resistor-capacitor (RC) network having a low-pass character.

### SUMMARY

### Technical Problem

Although impedance circuits can achieve very high frequency and broadband operation, their drawbacks are higher noise, higher current consumption, and poorer linearity. The noise current of a shunt resistor is inversely proportional with resistance, i.e., lower resistance generates higher noise. This is mitigated in some low noise amplifiers (LNAs) by noise cancelling, which adds complexity to the design. To have the same voltage swing (or maybe even higher to keep a signal to noise ratio (SNR) constant) at a lower load impedance, higher transconductance gm, i.e., higher current consumption is required. The linearity of such low impedance circuits is poorer since the load “consumes” some part of the supply voltage which can be utilized at the VDS of transistors.

As mentioned above, the high-frequency operation of operation amplifier (op-amp) based circuits is limited by the unity gain bandwidth (UGB) of the op-amp, which needs to be 5 to 10 times (depending on the linearity requirement) higher than the required bandwidth of the amplifier. With the reduced feature size of complementary metal-oxide-semiconductor (CMOS) technologies, this might still be possible at GHz frequencies, however at the cost of very high current consumption.

One of the main issues of tuned circuits is their limited bandwidth and non-flat frequency response. Nowadays, each sub-block in a network node transceiver chain, such as a base station transceiver chain, must have extremely flat frequency responses. Here, the requirement may be as low as 0.2 dB within the instantaneous bandwidth (IBW), the IBW increasing with every product generation.

Even though the bandwidth can be increased by lowering the Q-factor of the resonator (of course at the cost of higher current consumption, since Rp=L*ω*Q also goes down) the frequency response is, for all practical purposes, not entirely flat. Usually, there is a peak at the center (resonance frequency) with a droop around, that is a decrease or inclination downward around the resonance frequency.

To get a flat frequency response, other methods have been used. One of these methods is the double-tuning of a transformer (see, for example, https://en.wikipedia.org/wiki/Double-tuned amplifier) where coupling coefficient k between primary and secondary coils is optimized. Another method is to have several stages in series each of which are tuned in a staggered manner (see, for example, https://en.wikipedia.org/wiki/Staggered tuning). Another method is a Travelling Wave Amplifier (TWA, or Distributed Amplifier (DA)), where several amplifier stages are combined (see, for example https://en.wikipedia.org/wiki/Distributed_amplifier).

All three methods above improve bandwidth and flatness. However, staggered tuning and TWA need at least two stages that increase current consumption and the number of resonators, hence increasing costs and energy consumption. Double tuning of a transformer is attractive at the first sight. However, adding a secondary coil introduces large parasitic capacitance which makes it difficult to have both high inductance (needed at the low-end of the frequency range) and high self-resonance frequency (needed at the high-end) at the same time, limiting the frequency range.

There is thus a need to realize flat frequency response and broad bandwidth in a way that addresses the technical problems of the prior art.

### Solution

It may be an object of embodiments of the invention to realize flat frequency response and broad bandwidth while avoiding the technical problems arising from state of the art methods.

According to an aspect, an on-chip inductor comprises an inductor coil comprising a first sub-coil and a second sub-coil having mutual inductance, wherein the first sub-coil and the second sub-coil form a permanent electrical connection in series. The second sub-coil is placed inside the first sub-coil on the chip. Furthermore, the on-chip inductor comprises terminals connected to the first sub-coil and a resistor connected in parallel to the second sub-coil.

According to another aspect, an amplifier includes at least one on-chip inductor described above.

According to another aspect, a mixer includes at least one on-chip inductor described above.

According to another aspect, a semiconductor die has formed thereon at least one one-chip inductor described above.

According to another aspect, an electronic apparatus comprises a semiconductor die having formed thereon at least one on-chip inductor described above.

### BRIEF DESCRIPTION OF THE DRAWINGS

FIG. 1 shows an example of an amplifier placed in front of an RF ADC sampling at, for example, higher than 15 GHZ.

FIG. 2 shows the equivalent circuit of an exemplary broadband resonator.

FIG. 3 shows an example of the resonance of the broadband resonator.

FIG. 4 shows an example of an on-chip inductor having two sub-coils L1 and L2.

FIG. 5 shows an exemplary table including the features of the on-chip inductor illustrated in FIG. 4.

FIG. 6 shows an exemplary equivalent circuit of an inductor having a resistor.

FIG. 7 shows an example of a gain graph for different resistors.

FIG. 8A shows an example of realising an inductor having a first sub-coil L1, a second sub-coil L2, and a resistor Rres on a chip.

FIG. 8B shows an enlarged view of the resistor Rres and the inner terminal ports Ti1 and Ti2 of the inductor illustrated in FIG. 8A.

FIG. 9 shows exemplary results of an inductor comprising a 20Ω resistor.

FIG. 10 shows a comparison between three exemplary gain curves.

### DETAILED DESCRIPTION

Some of the embodiments contemplated herein will now be described more fully with reference to the accompanying drawings. Other embodiments, however, are contained within the scope of the subject matter disclosed herein, the disclosed subject matter should not be construed as limited to only the embodiments set forth herein; rather, these embodiments are provided by way of example to convey the scope of the subject matter to those skilled in the art.

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. Any feature of any of the embodiments disclosed herein may be applied to any other embodiment, wherever appropriate. Likewise, any advantage of any of the embodiments may apply to any other embodiments, and vice versa. Other objectives, features, and advantages of the enclosed embodiments will be apparent from the following description.

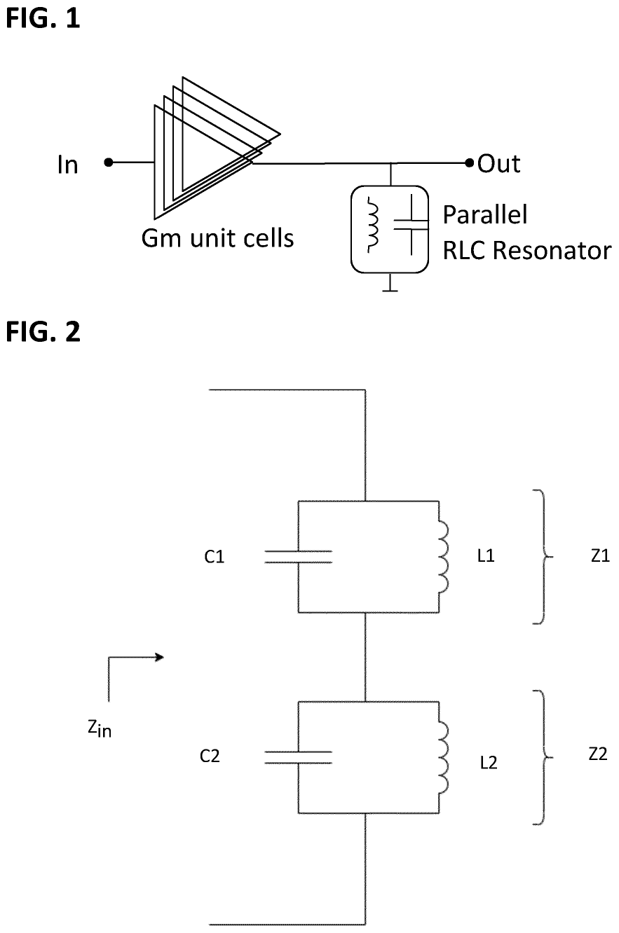

FIG. 1 shows an example of an amplifier placed in front of an RF ADC sampling at, for example, higher than 15 GHZ. Very briefly, gain and noise figure (NF) requirements are moderate, wherein frequency range (and flatness), maximum input power, and linearity requirements are challenging.

The Gm block consists of programmable unit cells to calibrate gain in PVT corners (i.e., corners of process, voltage, and temperature) and to save current when the gain is reduced. This is one of the advantages compared to an op-amp solution where current consumption is constant independent of the gain setting.

The parallel RLC resonator (R indicates the resistor, L indicates the inductor, and C indicates the capacitor) at the output is used to feed the supply voltage to the Gm cells with low IR drop, but also to filter out unwanted signals and noise. The load and parasitic capacitor are also “digested” while resonating with inductance. The resistor R of the RLC network is used to adjust the Q-factor (also known as Q-ratio) so that the bandwidth requirements are met.

FIG. 2 shows the equivalent circuit of an exemplary broadband resonator. L1 and L2 are inductors in series which are resonating with the capacitors C1 and C2, respectively. The underlying concept is to tune the values of L1 and L2 and the values of C1 and C2 so that two resonances cover the required frequency range in a staggered way.

The calculation for presenting the exemplary broadband resonator shown in FIG. 2 is included below:

$${Z}_{in} = {Z}_{1} + {Z}_{2}$$

$${Z}_{1} = \frac{\frac{1}{{sC}_{1}} \times {sL}_{1}}{\frac{1}{{sC}_{1}} + {sL}_{1}} = \frac{{sL}_{1}}{1 + {s}^{2} {L}_{1} {C}_{1}}$$

$${Z}_{2} = \frac{{sL}_{2}}{1 + {s}^{2} {L}_{2} {C}_{2}}$$

$${Z}_{in} = \frac{{sL}_{1}}{1 + {s}^{2} {L}_{1} {C}_{1}} + \frac{{sL}_{2}}{1 + {s}^{2} {L}_{2} {C}_{2}}$$

Zᵢₙ is the input impedance which is the addition of the impedances Z₁ and Z₂ in series. Z₁ refers to inductor L₁ and capacitor C₁ connected in parallel, whereas Z₂ refers to inductor L₂ and capacitor C₂ connected in parallel.

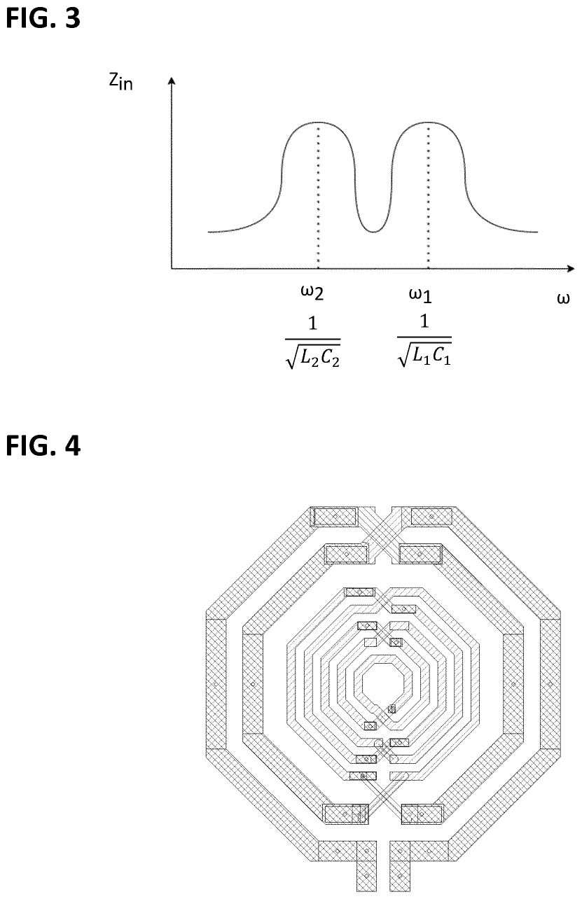

FIG. 3 shows an example of the resonance of the above-described broadband resonator. The combined impedance Zᵢₙ presents two distinct peaks at frequencies ω₂ and ω₁. Thus, no flat frequency response is achieved.

FIG. 4 shows an example of an on-chip inductor having two sub-coils L1 and L2. The on-chip inductor may be a realisation of the inductor included in the above-described broadband resonator, wherein the layout of the resonator may be done using the necessary technology, such as a corresponding design kit or the like. The capacitors C1 and C2 may not be realized by extra capacitors in the broadband resonator, but the intrinsic parasitic capacitances of the on-chip inductor are enough to realize sufficient values of C1 and C2.

As shown in FIG. 4, the sub-coils L1 and L2 may be drawn using metal layers. The width of the metal layers may impact the intrinsic parasitic capacitances. Sub-coil L2 is placed inside sub-coil L1. In other words, the inductor is implemented on a semiconductor chip (on-chip inductor) and the inner sub-coil L2 is positioned in an interior part which is enclosed by the outer sub-coil L1. In this example, sub-coil L1 has two wider turns, having a Q-factor of about 16 and a low inductance of about 1 nH. The sub-coil L2 has five narrower turns, having a lower Q-factor of about 7 and a higher inductance of about 2 nH. Including the feeding, i.e. the “legs” of the inductor where it is usually connected to other circuitry, the dimension of the whole structure may be 212 μm×233 μm.

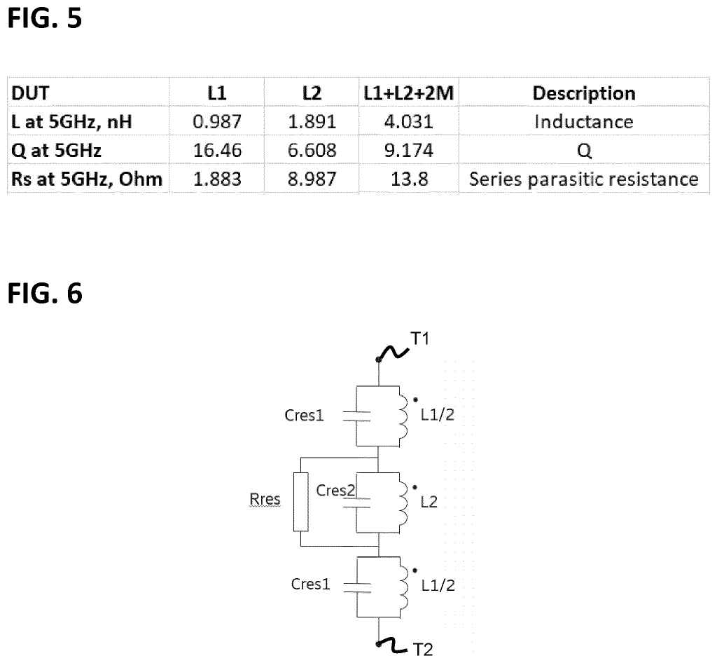

The extracted parameters of the inductor shown in FIG. 4 are summarized in the table of FIG. 5. The inductance, Q, and series resistance (Rs) values are extracted from S-parameters of the inductor.

As can be seen in FIG. 5, since the magnetic flux of the sub-coils L1 and L2 adds up, due to rotation in the same direction, the mutual inductance (2M) increases the total inductance of the inductor to approximately 4 nH. Mutual inductance means current through (or impedance on) one sub-coil impacts the other one. It is reciprocal, i.e., exists on both sub-coils with the same M value.

To flatten the distinct peaks shown in FIG. 3 and achieve a flat frequency response, the underlying concept is to appropriately use an additional resistor. A setup of an on-chip inductor having an appropriate additional resistor for realizing flat frequency response and broad bandwidth is described in more detail below.

According to an embodiment, an on-chip inductor is described which includes an inductor coil comprising a first sub-coil and a second sub-coil having mutual inductance. The on-chip inductor may be a planar inductor which is, for example, placed on a semiconductor chip (i.e. being implemented on an essentially two-dimensional plane on the chip). Mutual inductance means that the current through (or impedance on) one of the sub-coils impacts the other sub-coil. It is reciprocal, i.e., exists on both sub-coils with the same mutual inductance value.

The first sub-coil and the second sub-coil of the inductor coil may form a permanent electrical connection in series. By forming a permanent electrical connection, no sub-coil is disconnected from the other sub-coil using, for example, a switch or the like. Thus, when the inductor is in use, current continuously flows through both sub-coils.

The second sub-coil may be placed inside the first sub-coil on the chip and terminals may be connected to the first sub-coil. A resistor may be connected in parallel to the second sub-coil. For example, the resistor is a resistance wire, i.e., a wire or conductor intended for making a resistor or creating resistance; in other words, a passive electrical element according to Ohm's law. The resistance value of the resistor may be set by adjusting a width and/or a length of the resistance wire.

The first and second sub-coils may be configured such that the magnetic flux generated by the first and second sub-coils is in the same direction. The magnetic flux is generated due to electrical current flowing in a direction that is the same for the first and second sub-coils. Since the magnetic flux of both the first and second sub-coils adds up, due to rotation in the same direction, additive mutual inductance is created.

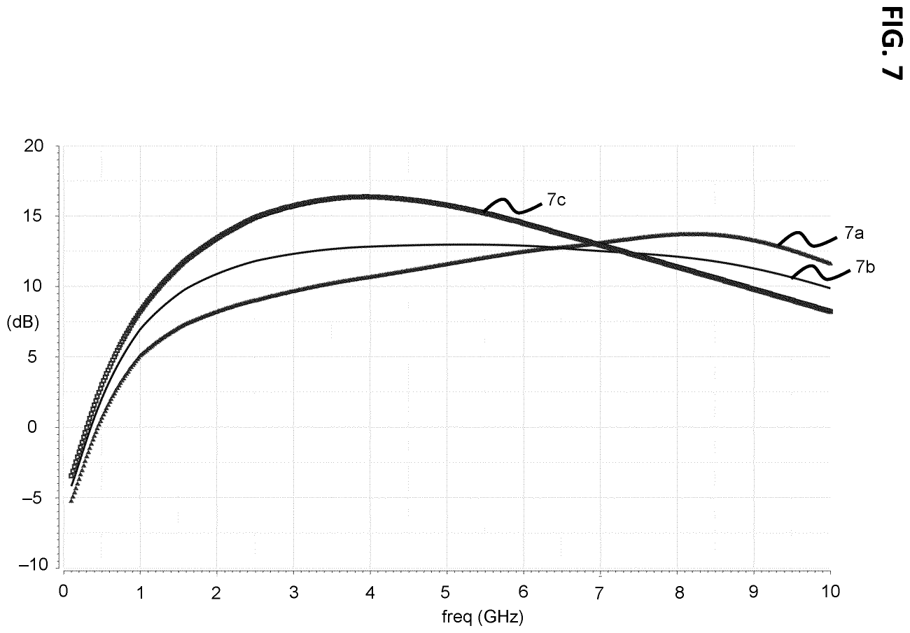

FIG. 6 shows an exemplary equivalent circuit of an inductor having a resistor. As explained above, the inductor may be an on-chip inductor. As shown in FIG. 6, the second sub-coil L2 being placed inside the first sub-coil L1 on, for example, the semiconductor chip can be represented in the equivalent circuit by an electrical connection in series in which a first part (e.g. first half L1/2) of the sub-coil L1 is electrically connected with the second sub-coil L2 and the second sub-coil L2 is further electrically connected with the other part (e.g. second half L1/2) of the sub-coil L1. Further, a resistor Rres is electrically connected in parallel to (only) the sub-coil L2. Cres1 and Cres2 represent capacitors which may be realized by capacitors connected in parallel to the first and second sub-coils L1 and L2 or which may be realized by the intrinsic parasitic capacitances of the inductor. T1 and T2 represent the terminals for supplying electrical current to the inductor.

FIG. 6 shows that the first and second sub-coils L1 and L2 can be configured in such a way that the electrical current flows from one of the terminals T1 of the inductor through a first half of the first sub-coil L1/2, the second sub-coil L2, and a second half of the first sub-coil L1/2 to another one of the terminals T2 of the inductor.

Cres1 and Cres2 may be adjusted to tune the individual resonances, whereas Rres may be adjusted to optimize the Q-factor or bandwidth. If Cres1 and Cres2 are realized by parasitic capacitances, Cres1 and Cres2 may be adjusted by adapting the configuration of the inductor, in particular the parameters (width, number of turns, etc.) of the respective conductors used for forming the sub-coils.

FIG. 7 shows an example of a gain graph for different resistors. Curve 7a shows the results of Rres=10Ω, curve 7b shows the results of Rres=20Ω, and curve 7c shows the results of Rres=50Ω. As can be seen in FIG. 7, the resonances and their Q-factors can be optimized for maximum flatness depending on the resistor Rres and its resistance. When Cres1=Cres2=1 fF and Rres=10Ω, for example, a resonator peak may appear between 8 GHZ and 9 GHZ (see curve 7a). When Cres1=Cres2=1 fF and Rres=50Ω, for example, a resonator peak may appear at around 4 GHZ (see curve 7c). An optimal result and, thus, a flat frequency response may be obtained for Cres1=Cres2=1 fF and Rres=200 (see curve 7b). These results suggest that the intrinsic parasitic capacitances of the inductor (intrinsic parasitic capacitances of the conductors used to form the respective sub-coils) are sufficient for achieving a maximally flat frequency response.

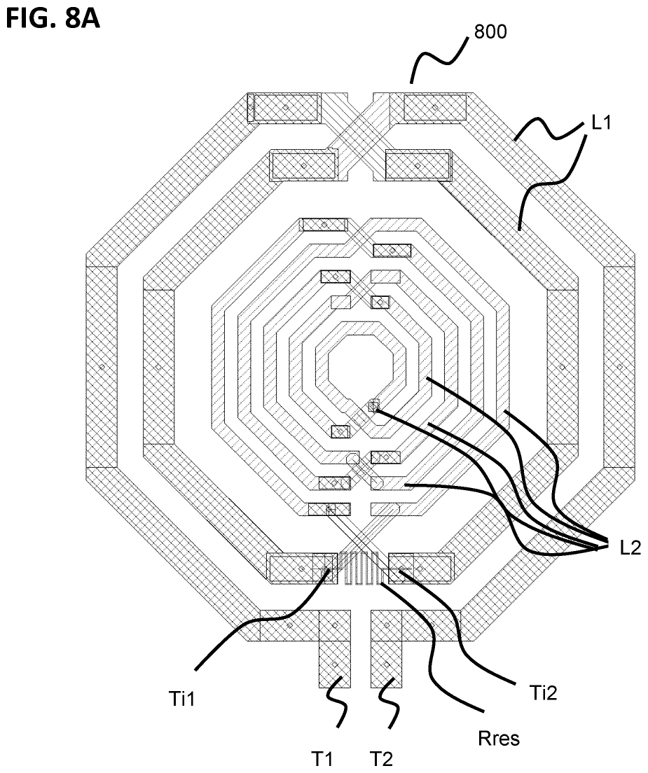

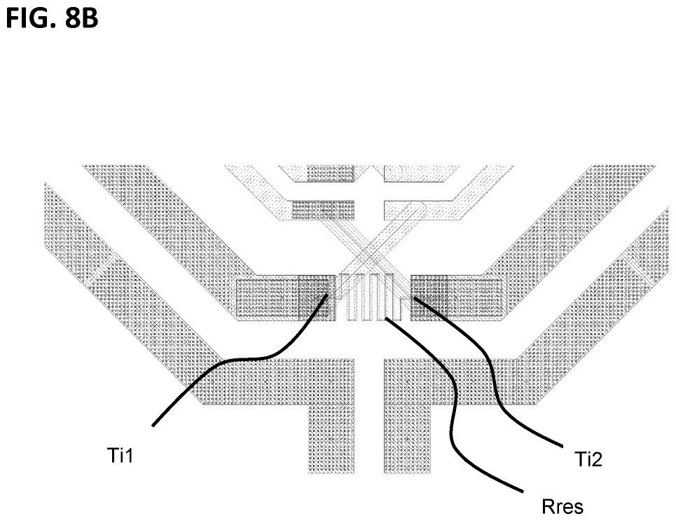

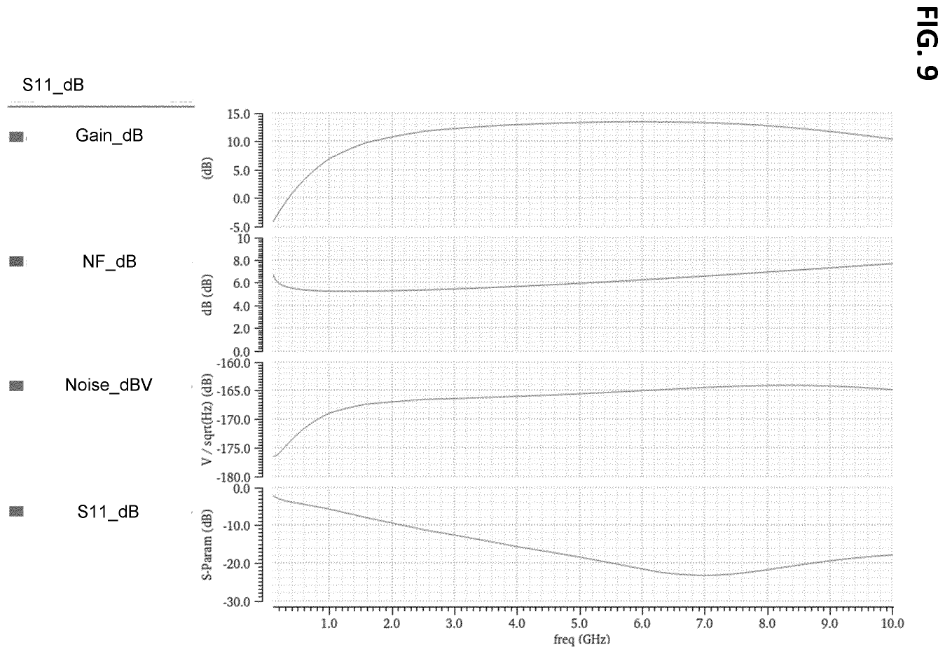

FIG. 8A shows an example of realising the above-described inductor having a first sub-coil L1, a second sub-coil L2, and a resistor Rres on a chip. The terminals which are connected to the first sub-coil L1 are indicated by T1 and T2. The terminals T1 and T2 may be placed outside of the windings of the first sub-coil L1. In FIG. 8A, the on-chip inductor is indicated with the reference sign 800. The skilled person understands that a first terminal T1 is structurally connected with the outer first sub-coil L1 which has a topology in which an outer turn of the first sub-coil L1 follows an outer circumference of the inductor to a side opposite of the terminals at which there is a first cross-section (e.g. via different layers of the semiconductor chip) and the electrical path of the first sub-coil follows an inner turn of the first sub-coil toward a terminal part Ti2 at the side of the terminals. At the terminal part Ti2, the inner turn of the first sub-coil L1 is structurally connected through a second cross-section (e.g. via different layers of the semiconductor chip) to the inner second sub-coil L2 having multiple turns inside the first sub-coil L1. The electrical path of the second sub-coil 12 is structurally connected (through a cross-section via different layers of the semiconductor chip) with a terminal port Ti1 of the inner turn of the first sub-coil L1 (across the other terminal port Ti2) so that the electrical path of the inner turn of the first sub-coil L1 follows adjacent to the outer circumference of the second sub-coil L2 toward the first cross-section and continues at an outer circumference of the inductor toward a second terminal T2 to complete the electrical loop of this permanent electrical connection (first part of the first sub-coil L1-second sub-coil L2-second part of the first sub-coil L1) in series.

According to an example, the first sub-coil L1 may have a smaller number of windings, a higher Q-ratio, and a lower inductance value as compared to the second sub-coil L2. In FIG. 8A, the first sub-coil L1 comprises two windings or turns and the second sub-coil L2 comprises five windings or turns. This is, however, not limiting and the two sub-coils may each comprise more or fewer windings.

As can be exemplary seen in FIG. 8A, the first sub-coil L1 and the second sub-coil L2 may be located on one plane, i.e., may not be located on top of each other. Since the two sub-coils L1 and L2 are not on top of each other, the coupling factor k is small yielding a low mutual inductance M value (k and M are directly proportional). For a given Q-ratio, there is an optimal value of k, wherein the frequency response is not flat when k is above or below the optimal value.

As already described above, the resistor Rres is connected in parallel to the second sub-coil L2. As exemplary shown in FIG. 8A, the inductor 800 may comprise a first inner terminal port Ti1 and a second inner terminal port Ti2 to form the permanent electrical connection between the first sub-coil L1 and the second sub-coil L2. The inner terminal ports Ti1 and Ti2 may be placed at the ends of the first sub-coil L1 and may be used together with a wire or metal layer to form a conductive path or conductive track and, thus, a permanent electrical connection between the sub-coils L1 and L2. As shown in FIG. 8A, the first inner terminal port Ti1 may be used to connect one end of the first sub-coil L1 with one end of the second sub-coil L2 and the second inner terminal port Ti2 may be used to connect another end of the first sub-coil L1 with another end of the second sub-coil L2.

In order to connect the resistor Rres in parallel to the second sub-coil L2, the resistor Rres may be placed between the first inner terminal port Ti1 and the second inner terminal port Ti2, see also FIG. 8A.

FIG. 8B shows an enlarged view of the resistor Rres and the inner terminal ports Ti1 and Ti2 of the inductor 800. As can be seen in FIG. 8B, the resistor Rres is placed between the first inner terminal port Ti1 and the second inner terminal port Ti2 and is electrically connected to the first inner terminal port Ti1 and the second inner terminal port Ti2.

The overall (effective) length of the resistor Rres may be longer than an actual distance between the first inner terminal port Ti1 and the second inner terminal port Ti2. In such a case, the resistor Rres may be shaped (e.g. folded or the like) to fit between the first inner terminal port Ti1 and the second inner terminal port Ti2. As exemplary shown in FIG. 8A and FIG. 8B, the resistor Rres may be meander-shaped to fit between the first inner terminal port Ti1 and the second inner terminal port Ti2. However, this is not limiting and any other shape for the resistor Rres may be possible.

According to an embodiment, the first sub-coil L1 and the second sub-coil L2 may each be constructed by a metal layer winding, wherein the metal layer winding of the second sub-coil L2 may be inside the metal layer winding of the first sub-coil L1. In other words, the two sub-coils may be drawn by using metal layers.

A width of the metal layer winding of the second sub-coil may be smaller than a width of the metal layer winding of the first sub-coil. The width of the metal layers may be measured in a direction orthogonal to the direction of the current flow through the sub-coils L1 and 12.

According to an embodiment, the resistor Rres may be constructed or realized by a metal layer winding, wherein a resistance value of the resistor may be set by adjusting a width and/or a length of the metal layer winding. The metal layer for the resistor Rres may be the same (within the semiconductor chip) as the metal layers for the sub-coils L1 and L2. The width may be measured in a direction orthogonal to the direction of the current flow through the resistor Rres, whereas the length may be measured in a direction of the current flow through the resistor Rres. Thus, the resonator including the inductor may be realized purely by metals and may have no components on silicon which leads to less impacts by process variations.

For example, the width of the metal layer winding constructing the resistor is smaller than the width of the metal layer windings constructing the first sub-coil L1 and the second sub-coil L2. The resistance value of the resistor Rres may be set to realize a flat frequency response. In other words, a specific resistance value can be selected (e.g. by selecting a length and width of the metal layer) for the inductor that achieves a flat frequency response.

For example, if a 20Ω resistor is needed for a flat frequency response, a lower metal layer, i.e. a metal layer physically closer to a silicon substrate, may be used for the resistor due to its higher sheet resistance compared to other metal layers used. To minimize the impact of process variations, the width of the metal layer for the resistor may be chosen as, for example, 0.5 μm which is roughly three times of the minimum width of 0.162 μm. Thus, by using wider metal layers or tracks, the sensitivity to process variations is reduced. To get a 20Ω resistance value, the resistor may be in a meander-shape to be able to be included in the inductor.

As described above, by providing an inductor having a resistor connected in parallel to the second sub-coil L2, a flat frequency response is achieved. Furthermore, the inductor realizes broadband operation, i.e. wideband operation, which means that a wide range of frequencies is accommodated by the inductor. Thus, the frequency bandwidth achieved by the above-described inductor is broad, i.e. wide or large.

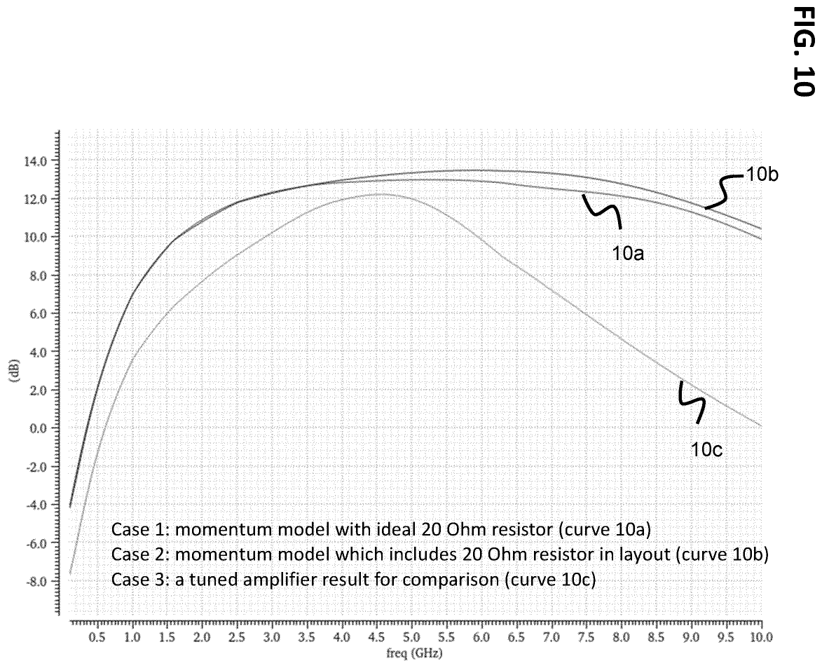

FIG. 9 shows exemplary results of an inductor comprising a 20Ω resistor. The inductor modelled in Momentum EM simulations. The inductor was simulated in an amplifier test bench yielding the results shown in FIG. 9. The graphs are: 1) a gain graph, 2) a noise figure (NF) graph, 3) a noise graph, and 4) a S-parameter graph. As can be seen from the gain graph, a usable frequency range from approximately 2 GHZ to 9 GHz is obtained, having a center frequency at around 5.5 GHz. The 0.2 dB cut-off bandwidth is at around 2.4 GHZ. Thus, a 2.4 GHz bandwidth with 0.2 dB variation and more than 5 GHZ bandwidth at 1 dB cut-off at a center frequency around 5.5 GHZ are achieved.

FIG. 10 shows a comparison between three exemplary gain curves. Curve 10a shows a Momentum EM model with an ideal 20 Ω resistor. Curve 10b shows a Momentum EM model with a non-ideal, i.e. practical or real-life, 20Ω resistor in layout. Curve 10c shows a tuned low noise amplifier (LNA) result as comparison. FIG. 10 shows that even with a non-ideal resistor, a flat frequency response is achieved.

Even though the above figures and embodiments describe a 20Ω resistor for achieving the best results, this is not limiting. Depending on the setup, another resistor may be ideal.

According to an embodiment, the above-described inductor may be included in an amplifier, a mixer, or the like. By ensuring a flat frequency response, a signal going into the amplifier is the same across the entire frequency spectrum as the signal coming out.

According to another embodiment, the above-described inductor may be formed on a semiconductor die.

The semiconductor die may be comprised in an electronic apparatus. The electronic apparatus may be a communication apparatus, such as a radio base station or wireless device for a cellular communications system, a Wifi access point or terminal, a Bluetooth device, or the like.

With the above-described inductor, a broadband resonator is provided which can directly replace the RLC resonator shown in FIG. 1. Several advantages of such inductor and broadband resonator is shown below:

The signal path is broadband, but it is still bandlimited, i.e., no anti-alias filters are required. Thus, advantages in band-pass characteristic are achieved.

Furthermore, both DC feeding supply voltage via inductor center tap and output swing on Vdd, enable good linearity as mentioned before.

Moreover, it has similar competitive figures to an amplifier with a tuned load. NF of the simulated topology is dominated by the input attenuator network, hence can be misleading.

A simple, shunt differential inductor structure may be the basis for the implementation of the inductor. As described above, only a 20Ω resistor was added, which may be realized by routing at a lower metal layer. Thus, simplicity is achieved. Instead of a 20Ω resistor, another resistor may be used to ensure a flat frequency response.

Also, the flexibility is improved. Inductances to create resonances at the low-end and high-end of the frequency range need different trade-offs. The parallel equivalent impedance of the resonator depends on Q-factor, inductance, and frequency (i.e. Rp=L*ω*Q) and the resonance frequency is inversely proportional to the square root of LC (i.e. ω=1/sqrt (LC)). So, low inductance at the higher-end, and higher inductance at the lower-end will be useful. When combined, both resonances need to complement each other in terms of center frequency and bandwidth, and they need to have the same equivalent impedance so that amplitude is constant over frequency. This means that the two inductors need to be optimized in concurrent iterations and they might end up having different numbers of turns, widths, etc, as is the case of the above-described solution. For example, achieving this with a transformer is difficult, since the primary and secondary sides do not have full flexibility, and impact each other much more. The only limitation in the above-described configuration is that sub-coil L2 shall fit inside sub-coil L1.

By implementing the proposed resonator structure and inductor structure only on a metal stack (see, for example, the metal layer windings described above), robustness can be increased. Hence, the inductor is robust against most of process variations. In case extra capacitors may be needed, e.g., in another design, these capacitors can also be implemented only on the metal stack (as metal on metal (MOM) caps or custom-made capacitors). Avoiding minimum metal widths may further increase robustness.

By using a metal stack of a state-of-the-art complementary metal-oxide-semiconductor (CMOS) process, it is possible to realize the broadband operation at a very attractive frequency range of the radio spectrum with reasonable coil dimensions. Thus, improved feasibility is achieved.

Furthermore, advantages in scalability are achieved. The physical dimensions of the coils will not be an issue in case it is desired to scale up the concept to higher frequencies since the coils will shrink. There is no obvious obstacle that might hinder operation at higher frequencies. Lower inductance (L) values will be balanced by higher frequency, hence Rp is expected to be relatively constant. Skin effect may reduce the Q-factor at higher frequencies.

It will be apparent to those skilled in the art that various modifications and variations can be made in the entities and methods of embodiments of this invention as well as in the construction of embodiments of this invention without departing from the scope of the invention.

The disclosure has been presented in relation to particular embodiments and examples which are intended in all aspects to be illustrative rather than restrictive. Those skilled in the art will appreciate that many different combinations of hardware, software and/or firmware will be suitable for practicing the teachings of the present disclosure.

Moreover, other implementations of the disclosure will be apparent to those skilled in the art from consideration of the specification and practice of the disclosure. It is intended that the specification and the examples be considered as exemplary only. To this end, it is to be understood that inventive aspects lie in less than all features of a single foregoing disclosed implementation or configuration. The scope of the invention is indicated by the following claims.

1. A semiconductor die having formed thereon an on-chip inductor, the on-chip inductor, comprising:
an inductor coil comprising a first sub-coil and a second sub-coil having mutual inductance, the first sub-coil and the second sub-coil forming a permanent electrical connection in series and the second sub-coil is placed inside the first sub-coil on the chip;
terminals connected to the first sub-coil; and
a resistor connected in parallel to the second sub-coil.

2. The semiconductor die according to claim 1, wherein the first and second sub-coils are configured such that a magnetic flux generated by the first and second sub-coils is in the same direction.

3. The semiconductor die according to claim 2, wherein the first and second sub-coils are configured such that an electrical current flows from one of the terminals through a first half of the first sub-coil, the second sub-coil, and a second half of the first sub-coil to another one of the terminals.

4. The semiconductor die according to claim 1, wherein the terminals are placed outside of windings of the first sub-coil.

5. The semiconductor die according to claim 1, wherein the first sub-coil and the second sub-coil are located on one plane.

6. The semiconductor die according to claim 1, wherein the first sub-coil has a smaller number of windings, a higher Q-ratio, and a lower inductance value as compared to the second sub-coil.

7. The semiconductor die according to claim 1, further comprising a first inner terminal port and a second inner terminal port to form the permanent electrical connection between the first sub-coil and the second sub-coil, wherein the first inner terminal port is used to connect one end of the first sub-coil with one end of the second sub-coil; and
wherein the second inner terminal port is used to connect another end of the first sub-coil with another end of the second sub-coil.

8. The semiconductor die according to claim 7, wherein the resistor is placed between the first inner terminal port and the second inner terminal port.

9. The semiconductor die according to claim 8, wherein an overall length of the resistor is longer than a distance between the first inner terminal port and the second inner terminal port; and
wherein the resistor is shaped to fit between the first inner terminal port and the second inner terminal port.

10. The semiconductor die according to claim 1, wherein the resistor is meander-shaped.

11. The semiconductor die according to claim 1, wherein the first sub-coil and the second sub-coil are each constructed by a metal layer winding, the metal layer winding of the second sub-coil being inside the metal layer winding of the first sub-coil.

12. The semiconductor die according to claim 11, wherein a width of the metal layer winding of the second sub-coil is smaller than a width of the metal layer winding of the first sub-coil.

13. The semiconductor die according to claim 11, wherein the resistor is constructed by a metal layer winding, and wherein a resistance value of the resistor is set by adjusting one or both of a width and a length of the metal layer winding.

14. The semiconductor die according to claim 13, wherein the resistance value of the resistor is set to realize a flat frequency response.

15. The semiconductor die according to claim 13, wherein the width of the metal layer winding constructing the resistor is smaller than the width of the metal layer windings constructing the first sub-coil and the second sub-coil.

16.-18. (canceled)

19. An electronic apparatus comprising a semiconductor die having formed thereon, the semiconductor die having formed thereon an on-chip inductor, the on-chip inductor, comprising:
an inductor coil comprising a first sub-coil and a second sub-coil having mutual inductance, the first sub-coil and the second sub-coil forming a permanent electrical connection in series and the second sub-coil is placed inside the first sub-coil on the chip;
terminals connected to the first sub-coil; and
a resistor connected in parallel to the second sub-coil.

20. The electronic apparatus according to claim 19, wherein the electronic apparatus is a communication apparatus.

21. The semiconductor die according to claim 1, wherein the on-chip inductor is included in an amplifier.

22. The semiconductor die according to claim 1, wherein the on-chip inductor is included in a mixer.

23. The electronic apparatus according to claim 19, further comprising a first inner terminal port and a second inner terminal port to form the permanent electrical connection between the first sub-coil and the second sub-coil, wherein the first inner terminal port is used to connect one end of the first sub-coil with one end of the second sub-coil; and
wherein the second inner terminal port is used to connect another end of the first sub-coil with another end of the second sub-coil.

24. The electronic apparatus according to claim 23, wherein the resistor is placed between the first inner terminal port and the second inner terminal port.

25. The electronic apparatus according to claim 24, wherein an overall length of the resistor is longer than a distance between the first inner terminal port and the second inner terminal port; and
wherein the resistor is shaped to fit between the first inner terminal port and the second inner terminal port.

26. The electronic apparatus according to claim 19, wherein the first sub-coil and the second sub-coil are each constructed by a metal layer winding, the metal layer winding of the second sub-coil being inside the metal layer winding of the first sub-coil.

27. The electronic apparatus according to claim 26, wherein the resistor is constructed by a metal layer winding, and wherein a resistance value of the resistor is set by adjusting one or both of a width and a length of the metal layer winding.

28. The electronic apparatus according to claim 19, wherein the first and second sub-coils are configured such that a magnetic flux generated by the first and second sub-coils is in the same direction.

29. The electronic apparatus according to claim 28, wherein the first and second sub-coils are configured such that an electrical current flows from one of the terminals through a first half of the first sub-coil, the second sub-coil, and a second half of the first sub-coil to another one of the terminals.
